(19) United States
(12) Patent Application Publication
(10) Pub. No.: US 2018/0175890 A1
(43) Pub. Date: Jun. 21, 2018

(54) Methods and Apparatus for Error Correction Coding Based on Data Compression

(71) Applicant: HYPERSTONE GMBH, Konstanz (DE)

(72) Inventors: Juergen Freudenberger, Radolfzell (DE); Mohammed I. M. Rajab, Konstanz (DE); Christoph Baumhof, Radolfzell (DE)

(21) Appl. No.: 15/848,012

(22) Filed: Dec. 20, 2017

(30) Foreign Application Priority Data
Dec. 20, 2016 (DE) 102016015167.6
Dec. 19, 2017 (DE) 102017130591.2

(51) Int. Cl. H03M 13/00; H04L 1/00; H03M 13/37

(52) U.S. Cl. CPC H03M 13/6312; H04L 1/0041; H03M 7/3068; H03M 13/3753; H04L 1/0045

(57) ABSTRACT

Embodiments are generally related to the field of channel and source coding of data to be sent over a channel, such as a communication link or a data memory. Some specific embodiments are related to a method of encoding data for transmission over a channel, a corresponding decoding method, a coding device for performing one or both of these methods and a computer program comprising instructions to cause said coding device to perform one or both of said methods.

### CROSS REFERENCE TO RELATED APPLICATIONS

The present application claims priority to German Patent Application No. 10 2016 015 167.6 entitled “A Channel and Source Coding Approach for the Binary Asymmetric Channel with Applications to MLC Flash Memories”, and filed Dec. 20, 2016; and German Patent Application No. 10 2017 130 591.2 entitled “Methods and Apparatus for Error Correction Coding based on Data Compression” and filed Dec. 19, 2017. The entirety of both of the aforementioned reference is incorporated herein by reference for all purposes.

### FIELD OF THE INVENTION

Embodiments are generally related to the field of channel and source coding of data to be sent over a channel, such as a communication link or a data memory. Some specific embodiments are related to a method of encoding data for transmission over a channel, a corresponding decoding method, a coding device for performing one or both of these methods and a computer program comprising instructions to cause said coding device to perform one or both of said methods.

### BACKGROUND

Flash memories are typically mechanical-shock-resistant non-volatile memories that offer fast read access times. Therefore, flash memories can be found in many devices that require high data reliability, e.g. in the fields of industrial robotics, and scientific and medical instrumentation. In a flash memory device, the information is stored in floating gates which can be charged and erased. These floating gates keep their electrical charge without a power supply. However, information may be read erroneously. The error probability depends on the storage density, the used flash technology (single-level cell (SLC), multi-level cell (MLC), or triple-level cell (TLC)) and on the number of program and erase cycles the device has already performed.

There exists a need in the art for enhanced methods and memory systems for data transfer and/or storage.

### SUMMARY

Embodiments are generally related to the field of channel and source coding of data to be sent over a channel, such as a communication link or a data memory. Some specific embodiments are related to a method of encoding data for transmission over a channel, a corresponding decoding method, a coding device for performing one or both of these methods and a computer program comprising instructions to cause said coding device to perform one or both of said methods.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phrases do not necessarily refer to the same embodiment. Many other embodiments of the invention will become more fully apparent from the following detailed description, the appended claims and the accompanying drawings.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 schematically illustrates an example embodiment of a system comprising a host and a channel comprising a flash memory device and a related coding device, according to embodiments of the present invention;

FIG. 2 schematically illustrates the voltage distribution of an example MLC flash memory and related read references voltages;

FIG. 3 shows a schematic illustration of a binary asymmetric channel (BAC);

FIG. 4 schematically illustrates various different codeword formats (i.e. coding schemes) which may be used in connection with various embodiments of the present invention;

FIG. 5 is a flow chart illustrating an example embodiment of an encoding method according to the present invention;

FIG. 6 is a flow chart illustrating an example embodiment of a decoding method according to the present invention;

FIG. 7 is a diagram showing graphs of distributions of index values after applying BWT and MTF algorithm for the actual relative frequency, the geometric distribution, and the log distribution;

FIG. 8 is a diagram showing numerical results for an MLC flash, where a, b, and c denote the respective coding formats of FIG. 4;

FIG. 9 is a diagram showing frame error rates resulting from different data compression algorithms for the example Calgary corpus, as a function of the program/erase (P/E) cycle count; and

FIG. 10 is a diagram showing frame error rates resulting from different data compression algorithms for the example Canterbury corpus, as a function of the program/erase (P/E) cycle count.

### DETAILED DESCRIPTION OF SOME EMBODIMENTS

Embodiments are generally related to the field of channel and source coding of data to be sent over a channel, such as a communication link or a data memory. In the latter case, “sending data over the channel” corresponds to writing, i.e. storing, data into the memory, and “receiving data from the channel” corresponds to reading data from the memory. In some embodiments, the data memory is non-volatile memory. In some particular instances of the aforementioned embodiments, such non-volatile memory is flash memory. Some specific embodiments are related to a method of encoding data for transmission over a channel, a corresponding decoding method, a coding device for performing one or both of these methods and a computer program comprising instructions to cause said coding device to perform one or both of said methods. It should be noted that while various embodiments discussed herein are described in the context of a memory, such as, for example, a flash memory, serving as the aforementioned channel, that the inventions presented are not limited to such channels. Rather, other implementations may also be used in connection with other forms of channels, such as wireline, wireless or optical communication links for data transmission.

The introduction of MLC and TLC technologies reduced the reliability of flash memories significantly compared to SLC flash (cf. [1]) (numbers in brackets refer to a respective document in the list of reference documents provided below). In order to ensure a reliable information storage, error correction coding (ECC) is required. For instance, Bose-Chaudhuri-Hocquenghem (BCH) codes (cf. [2]) are often used for error correction (cf. [1], [3], [4]). Moreover, concatenated coding schemes were proposed, e.g., product codes (cf.[5]), concatenated coding schemes based on trellis coded modulation and outer BCH or Reed-Solomon codes (cf. [6], [7], [8]), and generalized concatenated codes (cf. [9], [10]). With multi-level cell and triple-level cell technologies, the reliability of the bit levels and cells varies. Furthermore, asymmetric models are required to characterize the flash channel (cf. [11], [12], [13], [14]). Coding schemes were proposed that take these error characteristics into account (cf. [15], [16], [17], [18]).

On the other hand, data compression is less frequently applied for flash memories. Nevertheless, data compression can be an important ingredient in a non-volatile storage system that improves the system reliability. For instance, data compression can reduce an undesirable phenomenon called write amplification (WA) (cf. [19]). WA refers to the fact that the amount of data written to the flash memory is typically a multiple of the amount intended to be written. A flash memory must be erased before it can be rewritten. The granularity of the erase operation is typically much smaller than that of the write operation. Hence, the erase process results in rewriting of user data. WA shortens the life time of flash memories.

Some embodiments of the present inventions improve the reliability of sending data over a channel. In some cases, this improvement includes enhancing the reliability of storing into and reading data from a flash memory, such as a MLC and TLC flash memory, and thus also extend the lifetime of such flash memory.

Various embodiments of the present inventions provide methods of encoding data for transmission over a channel, such as a non-volatile memory. In some instances, the non-volatile memory is a flash memory. The method is performed by a coding device and comprises: (i) obtaining input data to be encoded; (ii) applying a predetermined data compression process to the input data to reduce redundancy, if any, to obtain compressed data; (iii) selecting a code from a predetermined set C={ [symbol] ⱼ, i=1 . . . N; N>1} of N error correction codes [symbol] ᵢ, each having a length n being the same for all codes of the set C, a respective dimension kᵢ and error correction capability tᵢ, wherein the codes of the set C are nested such that for all i=1, . . . , N−1: [symbol] ᵢ⊃ [symbol] ᵢ₊₁, kᵢ>kᵢ₊₁ and tᵢ<tᵢ₊₁; and (iv) obtaining encoded data by encoding the compressed data with the selected code. Therein, selecting the code comprises determining a code [symbol] ⱼ with j ∈{1, . . . , N} from the set C as the selected code, such that kⱼ≥m, wherein m is the number of symbols in the compressed data and m<n.

Of course, in the special case that the input data does not contain any redundancy which could be removed by performing said compression, the data resulting from applying said compression process may indeed be not compressed at all relative to the input data. Specifically, in this particular case, the data resulting from applying said compression process may even be identical to the input data. As used herein, the term “compressed data” shall, therefore, generally refer to the data resulting from applying said compression process to the input data, even if, for a specific selection of input data, no actual compression can be achieved therewith.

Application of the data compression process allows for a reduction of the amount of input data (e.g., user data), such that the redundancy of the error correction coding can be increased. In other words, at least a portion of the amount of data that is saved due to the compression is now used for additional redundancy, such as additional parity bits. This additional redundancy improves reliability of sending data over the channel, such as a data storage system. Moreover, data compression can be utilized to exploit the asymmetry of the channel.

Furthermore, the coding scheme uses a set C of two or more different codes, where the decoder can resolve which code was used. In the case of two codes, two nested codes [symbol] ₁ and [symbol] ₂ of length n and dimensions k₁ and k₂ are used, where nested means that [symbol] ₂is a subset of [symbol] ₁. The code [symbol] ₂has the smaller dimension k₂<k₁ and higher error correction capability t₂>t₁. If the data can be compressed such that the number of compressed bits is less or equal to k₂, the code [symbol] ₂ is used to encode the compressed data, otherwise the data is encoded using [symbol] ₁. Particularly, an additional information bit in the header may be used to indicate whether the data was compressed. Because [symbol] ₂⊂ [symbol] ₁, the decoder for [symbol] ₁ may also be used to decode data encoded with [symbol] ₂ up to the error correction capability t₁. Thus, if the actual number of errors is less or equal to t₁ the decoder can successful decode. If the actual number of errors is greater than t₁, it is assumed that the decoder for [symbol] ₁ fails. The failure can often be detected using algebraic decoding. Moreover, a failure can be detected based on error detection coding and based on the data compression scheme, because the number of data bits is known, the decoding fails if the number of reconstructed data bits is not consistent with the data block size. In cases where the decoding of [symbol] ₁ fails, the decoder may now continue the decoding using [symbol] ₂ which can correct up to t₂ errors. In summary, for sufficiently redundant data, the decoder can thus correct up to t₂ errors. In particular, in the case of a channel comprising flash memory, this allows for a significant improvement of the program/erase-cycling endurance and thus an extension of the lifetime of the flash memory

The example embodiments of a encoding method discussed herein can be arbitrarily combined with each other or with other aspects of the present invention, unless such combination is explicitly excluded or technically impossible.

In some embodiments, selecting the code comprises actively performing a selection process, e.g. according to a setting of one or more selectable configuration parameters, while in some other embodiments the selection of a particular code is already preconfigured in the coding device, e.g. as a default setting, such that no further active selection process is necessary. This pre-configuration approach is particularly useful in the case of N=2, where obviously there is only one choice for the code (1)=C₁ of the initial iteration I=1 such that a second iteration I=2 remains possible, such that [symbol] (2)=C₂ ⊂C₁. Also a combination of these two approaches is possible, e.g. a default configuration which may be adjusted by reconfiguring the one or more parameters.

In some embodiments, determining the selected code comprises selecting that code from the set C as the selected code Cⱼ, which has the highest error correction capability tⱼ=max {tᵢ} among all codes in C for which kᵢ≥m. This allows for an optimization of the additional reliability for the sending of data over the channel, such as a flash memory, which can be achieved by performing the method.

In some further embodiments, the channel is an asymmetric channel, such as—without limitation—a binary asymmetric channel (BAC), for which a first kind of data symbols, e.g. a binary “1”, exhibits a higher error probability than a second kind of data symbols, e.g. a binary “0”. In addition, obtaining encoded data comprises padding at least one symbol of a codeword of the encoded data, which symbol is not otherwise occupied by the applied code (e.g. by user data, header, parity), by setting it to be a symbol of the second kind. In fact, there are kᵢ−m such symbols. The asymmetric channel may particularly comprise or be formed by a non-volatile memory, such as flash memory. The padding may thus be employed to reduce the probability of a decoding error by reducing the number of symbols of the first kind (e.g. binary “1”) in the codeword.

In some further embodiments, applying the compression process comprises sequentially applying a Burrows-Wheeler-transform (BWT), a Move-to-front-coding (MTF), and a fixed Huffman encoding (FHE), to the input data to obtain the compressed data. Therein, the fixed Huffman code to be applied in the FHE is derived from an estimate of the output distribution of the previous sequential application of both the BWT and the MTF to the input data. In particular, these embodiments may relate to a lossless source coding approach for short data blocks that uses a BWT as well as a combination of an MTF algorithm and Huffman coding. A similar coding scheme is for instance used in the bzip2 data compression approach [23]. However, bzip2 is intended to compress complete files. The controller unit for a flash memory operates on a block level with typical block sizes of 512 byte up to 4 kilobytes. Thus, the data compression has to compress small chunks of user data, because blocks might be read independently. In order to adapt the compression algorithm to small block sizes, according to these embodiments, the output distribution of the combined BWT and MTF algorithm is estimated and a fixed Huffman code is used instead of adaptive Huffman coding. Hence, storing or adaptation of code tables can be avoided.

Specifically, according to some related embodiments, the estimate of the output distribution P(l) of the previous sequential application of the BWT and the MTF to the input data is determined as follows:

$$P ( 1 ) = {P}_{1} = const . \\ P ( i ) = \frac{1}{i ( {P}_{2} + {\sum }_{j = 2}^{M} \frac{1}{j} )} for i ∈ \{ 2 , . . . , M \} .$$

wherein M is the number of symbols to be encoded by the FHE.

In some related embodiments, the parameters M and P(1) are selected as M=256 and 0.37≤P₁≤0.5. A selection, may be specifically: M=256 and P₁=0.4. These selections relate to particularly efficient implementations of the compression process and particularly allow for achieving a good degree of data compression

In some further embodiments, the set C={ [symbol] ᵢ, i=1 . . . N; N>1} of error correction codes [symbol] ᵢ contains only two of such codes, i.e. N=2.This allows for a particularly simple and efficient implementation of the encoding method, since only two codes have to be stored and processed. This may result in one or more of the following advantages: a more compact implementation of the decoding algorithm, lower storage space requirements, and shorter decoding times.

One or more embodiments of the present inventions provide methods of decoding data, the method being performed by a decoding device, or—more generally—by a coding device (which may for example at the same time also be an encoding device). Such methods comprise obtaining encoded data, such as, for example, data being encoded according to the encoding method of the first aspect; and iteratively:
(a) performing a selection process comprising selecting a code [symbol] (I) of a current iteration I from a predetermined set C={ [symbol] ᵢ, i=1 . . . N; N>1} of N error correction codes [symbol] ᵢ, each having a length n being the same for all codes of the set C, a respective dimension kᵢ and an error correction capability tᵢ, wherein the codes of the set C are nested such that for all i=1 . . . N−1: [symbol] ᵢ⊃ [symbol] ᵢ₊₁, kᵢ>kᵢ₊₁ and tᵢ<tᵢ₊₁, wherein [symbol] (I)⊃ [symbol] (I+1) and [symbol] (1)⊃ [symbol] _{N} for the initial iteration I=1;
(b) performing a decoding process comprising sequentially decoding the encoded data with the selected code of the current iteration I and applying a predetermined decompression process to obtain reconstructed data of the current iteration I;
(c) performing a verification process comprising detecting whether the decoding process of the current iteration I resulted in a decoding failure; and
(d)) if in the verification process of the current iteration I a decoding failure was detected, proceeding with the next iteration I :=I+1; and
(e) otherwise, outputting the reconstructed data of the current iteration I as decoded data. For some codes, including particularly BCH codes, in step (b), a current iteration I>1 may continue the decoding based on the intermediate decoding result of the immediately preceding iteration I−1, while for some other codes each iteration, i.e. not only the initial iteration I=1, may have to start from the original encoded data instead. Of course, counting the iterations specifically by an integer index I and setting I=1 for the initial iteration refers only to one of many possible implementations and nomenclatures and is not meant to be limiting, but is rather used here to provide a particularly compact formulation of the inventions.

This decoding method is specifically based on the concept to use a set C of nested codes, as defined above. Accordingly, it is possible to use an initial code [symbol] ₁ for the initial iteration, that has a lower error correction capability t₁ than the codes being selected for subsequent iterations. More generally, this applies for any two subsequent codes [symbol] ₁ and [symbol] ᵢ₊₁. If the initial code [symbol] ₁ used in the initial iteration already leads to a successful decoding, the further iterations can be omitted. Furthermore, as any one of the codes [symbol] ₁ has a lower error correction capability tᵢ than its subsequent code [symbol] ᵢ₊₁the decoding efficiency of code [symbol] ᵢ will generally be higher than that of code [symbol] ᵢ₊₁. Accordingly, the less efficient higher code [symbol] ᵢ₊₁ will only be used, if the decoding based on previous code [symbol] ᵢ failed. As the codes are nested such that [symbol] (I+1)⊂ [symbol] (I), [symbol] (I+1)only comprises codewords which are also present in [symbol] (I), and thus this iterative process becomes possible, which allows to not only improve the reliability of sending data over the channel but also to perform the related decoding in a particularly efficient manner, as the more demanding iteration steps of the decoding process only need to performed, if all previous less demanding iterations have failed to successfully decode the input data.

The example embodiments of a decoding method discussed herein can be arbitrarily combined with each other or with other aspects of the present invention, unless such combination is explicitly excluded or technically impossible.

In some embodiments, the verification process further comprises: if for the current iteration I a decoding failure was detected, determining, before proceeding with the next iteration, whether another code [symbol] (I+1)⊂ [symbol] (I) exists in the set C, and if not, terminating the iteration and outputting an indication of a decoding failure. Accordingly, in this way a simple-to-test termination criterion for the iteration is defined, which can be easily implemented and which is efficient and ensures that a further iteration step is only initiated if a corresponding code is actually available.

In some further embodiments, detecting whether the decoding process of the current iteration I resulted in a decoding failure comprises one or more of the following: (i) algebraic decoding; (ii) determining, whether the number of data symbols in the reconstructed data of the current iteration is inconsistent with a known corresponding number of data symbols in the original data to be reconstructed by the decoding. Both of these approaches allow for an efficient detection of decoding failures. Specifically, approach (ii) is particularly adapted to decoding of data received from a channel comprising or being formed of an NVM, such as a flash memory, where data is stored in memory blocks of a predefined known size.

Like in the case of the encoding method of the first aspects, in some further embodiments, the set C={ [symbol] i, i=1 . . . N; N>1}of N error correction codes [symbol] i, of error correction codes [symbol] i contains only two of such codes, i.e. N=2. This allows for a particularly simple and efficient implementation of the method of decoding, as only two codes have to be stored and processed, which may correspond to one or more of the following advantages: a more compact implementation of the decoding algorithm, lower storage space requirements, and shorter decoding times.

Yet other embodiments of the present inventions provide coding devices, which may for example and without limitation specifically be a semiconductor device comprising a memory controller. The coding device is adapted to perform the encoding method of the first aspect and/or the decoding method of the second aspect of the present invention. In particular, the coding device may be adapted to perform the encoding method and/or the decoding method according to one or more related embodiments described herein.

In some cases, the coding devices include (i) one or more processors; (ii) memory; and (iii) one or more programs being stored in the memory, which when executed on the one or more processors cause the coding device to perform the encoding method of the first aspect and/or the decoding method of the second aspect of the present invention, for example—and without limitation—according to one or more related embodiments described herein.

Yet additional embodiments of the present inventions provide computer programs comprising instructions to cause a coding device, such as the coding device of the third aspect, to perform the encoding method of the first aspect and/or the decoding method of the second aspect of the present invention, for example—and without limitation—according to one or more related embodiments described herein.

The computer program product may in particular be implemented in the form of a data carrier on which one or more programs for performing said encoding and/or decoding method are stored. Preferably, this is a data carrier, such as an optical data carrier or a flash memory module. This may be advantageous, if the computer program product is meant to be traded as an individual product independent from the processor platform on which the one or more programs are to be executed. In another implementation, the computer program product is provided as a file on a data processing unit, in particular on a server, and can be downloaded via a data connection, e.g. the Internet or a dedicated data connection, such as a proprietary or local area network.

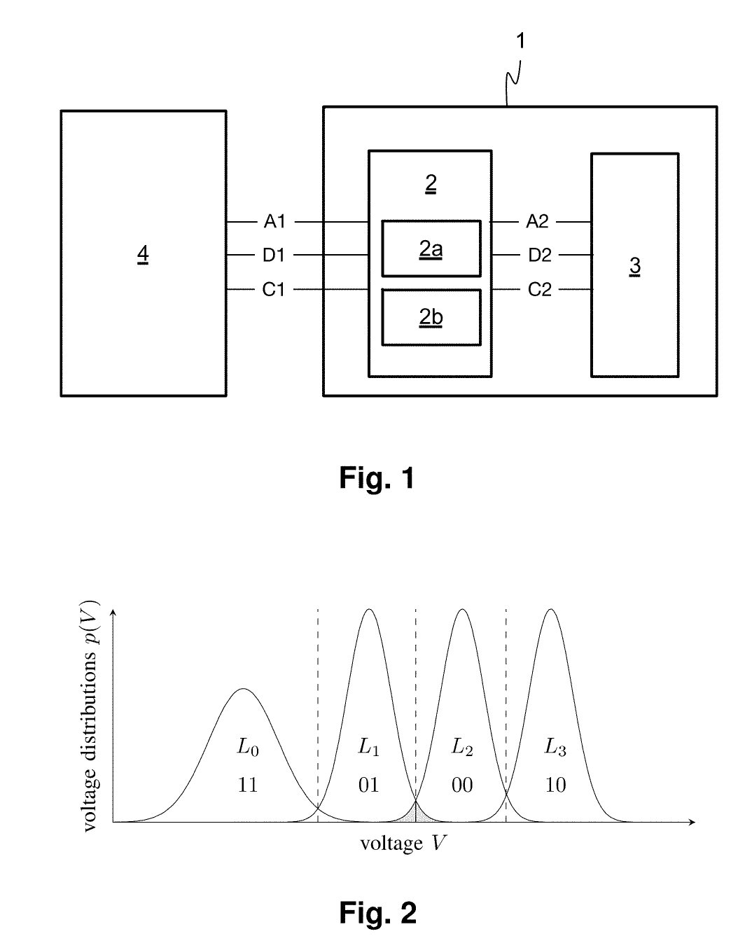

FIG. 1 shows an example memory system 1 comprising a memory controller 2 and a memory device 3, which may particularly be a flash memory device, e.g. of the NAND type. The memory system 1 is connected to a host 4, such as a computer to which the memory system 1 pertains, via a set of address lines A1, a set of data lines D1 and set of control lines C1. The memory controller 2 comprises a processing unit 2a and an internal memory 2b, typically of the embedded type, and is connected to the memory 3 via an address bus A2, a data bus D2, and a control bus C2. Accordingly, host 4 has indirect read and/or write access to the memory 3 via its connections A1, D1 and C1 to the memory controller 2, which in turn can directly access the memory 3 via the buses A2, D2 and C2. Each of the set of lines respectively buses A1, D1, C1, A2, D2 and C2 may be implemented by one or more individual communication lines. Bus A2 may also be absent.

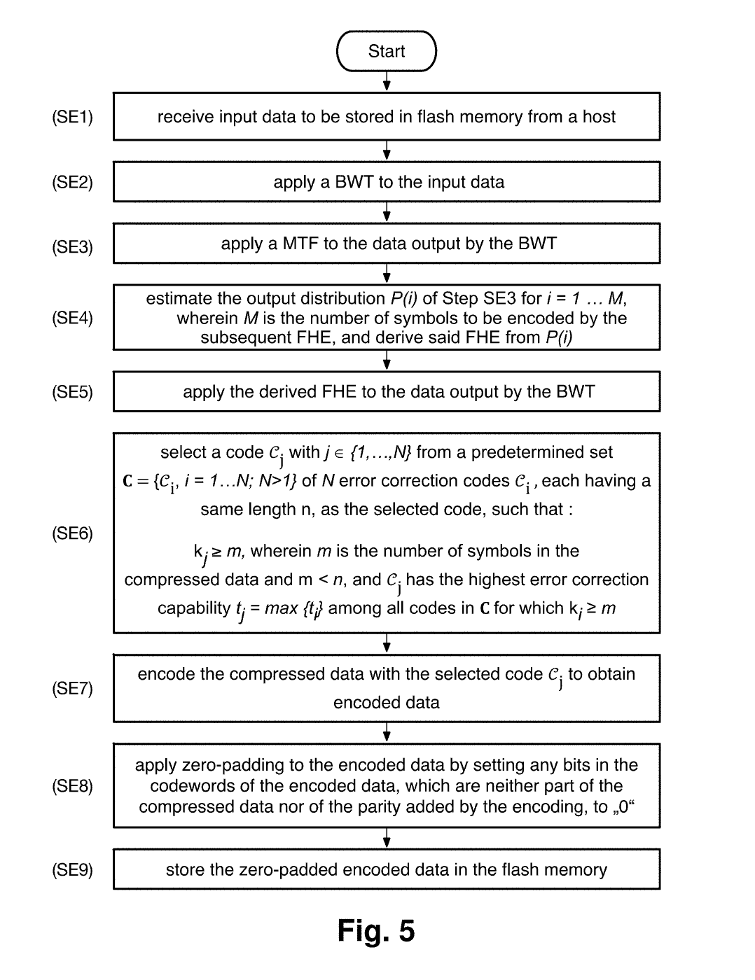

The memory controller 2 is also configured as a coding device and adapted to perform the encoding and decoding methods of the present invention, particularly as described below with reference to FIGS. 5 to 10. Thus, memory controller 2 is enabled to (i) encode data received from the host and to store the encoded data in the memory 3 and (ii) to decode encoded data read from the memory device 3. To that purpose, the memory controller 2 may comprise one or more computer programs residing in its internal memory 2b which is configured to perform this encoding and decoding methods when executed on the processing unit 2a of the memory controller 2. Alternatively, the program may for example reside, in whole or in part, in memory device 3 or in an additional program memory (not shown) or may even be implemented in whole or part by a hard-wired circuit. Accordingly, the memory system 1 represents a channel to which the host 4 may send data or receive data therefrom.

FIG. 2 illustrates an example voltage distribution of an MLC flash memory cell (cf. [12] or [13] for actual measurements). In FIG. 2, the x-axis represents voltages and the y-axis represents the probability distributions of programmed voltages (corresponding to charge levels). Three reference voltages are predefined to differentiate the four possible states during the read process. Each state (L0, . . . , L3) encodes a 2-bit value that is stored in the flash cell (e.g., 11, 01, 00, or 10), where the first bit is the most significant bit (MSB) and the last bit is the least significant bit (LSB). A NAND flash memory is organized as thousands of two-dimensional arrays of flash cells, called blocks and pages. Typically, the LSB and MSB are mapped to different pages. To read an LSB page, only one read reference voltage needs to be applied to the cell. To read the MSB page, two read reference voltages need to be applied in sequence.

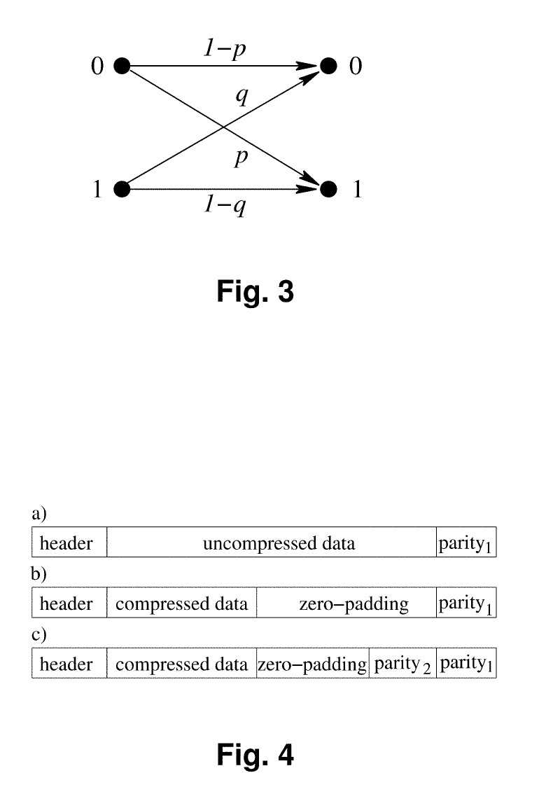

As indicated by FIG. 2, the standard distribution varies from state to state. Hence, some states are less reliable. This results in different error probabilities for the LSB and MSB pages. Moreover, the error probability is not equal for zeros and ones, where the error probabilities can differ by more than two orders of magnitude [14]. As indicated in [14], this error characteristic may be modeled as a binary asymmetric channel (BAC) which is illustrated in FIG. 3. It has a probability p that an input 0 will be flipped into a 1 and a probability q for a flip from 1 to 0. In the following, for the error probabilities p and q the assumption is made—solely for the sake of illustration and without limitation—that q>p.

The basic codeword format for an error correcting code with flash memories is illustrated in FIG. 4a). We assume coding with an algebraic error correcting code (e.g. a BCH code) of length n and error correction capability t, but the proposed coding scheme can also be used with other error correcting codes. The encoding is typically systematic and operates on data block sizes of 512 byte, 1 kilobyte, 2 kilobytes, or 4 kilobytes. In addition to the data and the parity for error correction, typically some header information is stored which contains additional parity bits for error detection.

For the applications in storage systems, the number of code bits n is fixed and cannot be adapted to the redundancy of the data. A basic idea of some embodiments of the coding scheme presented herein is to use the redundancy of the data in order to improve the reliability, i.e. reducing probability of a decoding error, by reducing the number n₁ of ones (“1”), or more generally the kind of symbol for which the corresponding error probability is higher than for another symbol (or in the case of binary coding the other kind of symbol),in the codeword. In order to reduce n₁, the redundant input data to be encoded is compressed and zero-padding is used,as illustrated in FIG. 4b). Furthermore, the reliability may be improved by using more parity bits and hence a higher error correction capability, as indicated in FIG. 4c). However, increasing the error correction capability also increases the decoding complexity. Moreover, the error correction capability should be known for decoding the error correcting code.

FIG. 5 is a flow chart illustrating an example embodiment of an encoding method according to the present invention. For the purpose of illustration, the method is exemplarily described in connection with a memory system 1, as illustrated in FIG. 1, the BAC of FIG. 3 and the coding schemes of FIG. 4. The method starts with a step SE1, wherein the memory controller 2, that serves as a coding device, now specifically as an encoding device, receives from host 4 input data to be stored in the flash memory 3. The method further comprises a lossless data compression scheme that is particularly suitable for short data blocks and which comprises several stages corresponding to subsequent steps SE2 to SE5. The compression scheme is applied to the input data in order to compress same. At first, in step SE2, a Burrows-Wheeler-transform (BWT) is applied to the input data, followed by application of a Move-to-front-coding (MTF) in step SE3 to the data output by step SE2.

The Burrows-Wheeler transform is a reversible block sorting transform [28]. It is a linear transform designed to improve the coherence in data. The transform operates on a block of symbols of length N to produce a permuted data sequence of the same length. In addition, a single integer i∈{1, . . . , K} is calculated which is required for the inverse transform. The transform writes all cyclic shifts of the input data into a K×K matrix. The rows of this matrix are sorted in lexicographic order. The output of the transform is the last column of the sorted matrix plus an index which indicates the position of the first input character in the output data. The output is easier to compress because it has many repeated characters due to the sorting of the matrix.

An adaptive data compression scheme has to estimate the probability distribution of the source symbols. The move-to-front algorithm (MTF), also introduced as recency rank calculator by Elias [29] and Willems [30], is an efficient method to adapt to the actual statistics of the user data. Similar to the BWT, the MTF algorithm is a transformation where a message symbol is mapped to an index. The index r is selected for the current source symbol if r different symbols occurred since the last appearance of the current source symbol. Later on, the integer r is encoded to a codeword from a finite set of codewords of different lengths. In order to keep track of the recency of the source symbols, the symbols are stored in a list ordered according to the occurrence of the symbols. Source symbols that occur frequently, remain close to the first position of the list, whereas more infrequent symbols will be shifted towards the end of the list. Consequently, the probability distribution of the output of an MTF tends to be a decreasing function of the index. The length of the list is determined by the number of possible input symbols. Here, for the purpose of illustration, a byte wise processing is used, hence a list with M=256 entries is used.

The final step SE5 of the compression scheme is a Huffman encoding [31], wherein a variable-length prefix code is used to encode the output values of the MTF algorithm. This encoding is a simple mapping from a binary input code of fixed length to a binary variable-length code. However, the optimal prefix code should be adapted to the output distribution of the previous encoding stages. For example, the known bzip2 algorithm, which also uses Huffman encoding, stores to that purpose a coding table with each encoded file. For the encoding of short data blocks, however, the overhead for such a table would be too costly. Therefore, in contrast to the bzip2 algorithm, the present encoding method uses a fixed Huffman code which is derived from an estimate of the output distribution of the BWT and MTF encoding. Accordingly, in the method of FIG. 5, such a fixed Huffman encoding (FHE) is applied to the output of the MTF step SE3 to obtain the compressed data.

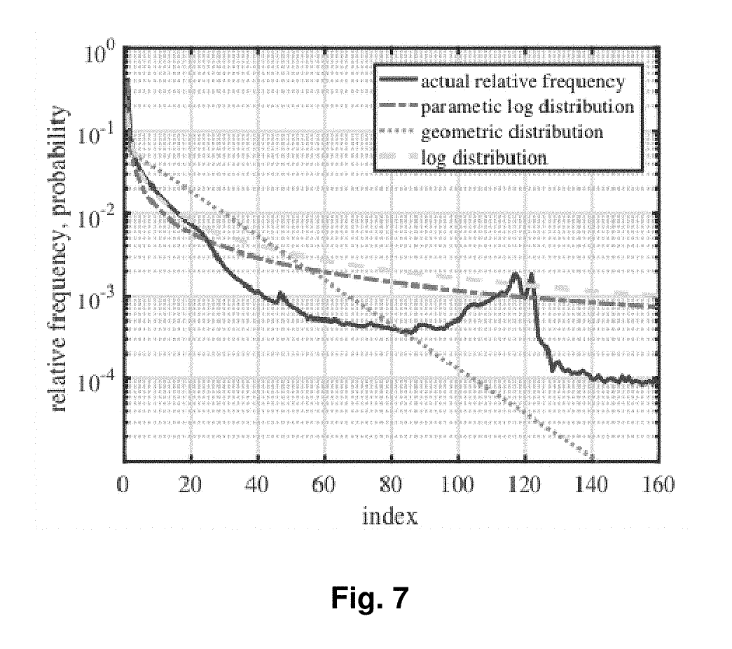

Step SE4, which precedes step SE5, serves to derive the FHE to be applied in step SE5 from an estimate of the output distribution of step SE3, i.e. of the consecutive application of the BWT and MTF in steps SE2 and SE3. Step SE4 will be discussed in more detail below with reference to FIG. 7.

In a further step SE6, which follows the compression of the input data in steps SE2 to SE5, a code Cⱼ is selected from a predetermined set C={ [symbol] ᵢ, i=1 . . . N; N>1} of N error correction codes [symbol] ᵢ, each having a length n being the same for all codes of the set C, a respective dimension kᵢ and error correction capability tᵢ. The codes of the set C are nested such that for all i=1, . . . , N−1: [symbol] ⊃ [symbol] ᵢ₊₁, kᵢ>kᵢ₊₁ and tᵢ<tᵢ₊₁. Specifically, in this example, that particular code from the set C is chosen as the selected code Cⱼ, which has the highest error correction capability tⱼ=max {tᵢ} among all codes in C for which kᵢ≥m.

Then, in a further step SE7, the compressed data is encoded with the selected code Cⱼ to obtain encoded data. In addition, in a step SE8, which may follow step SE7 or be applied simultaneously therewith or even as an integral process within the encoding of SE7, zero-padding is applied to the encoded data by setting any “unused” bits in the codewords of the encoded data, i.e. bits which are neither part of the compressed data nor of the parity added by the encoding, to “0” (as in the BAC of the present example q>p). As discussed above, this zero-padding in step SE8 is a measure to further increase the reliability of sending data over the channel, i.e. in this example, the reliability of storing data to the flash memory 3 and subsequently retrieving it therefrom. Then, in a further step SE9 the encoded and zero-padded data is stored into the flash memory 3.

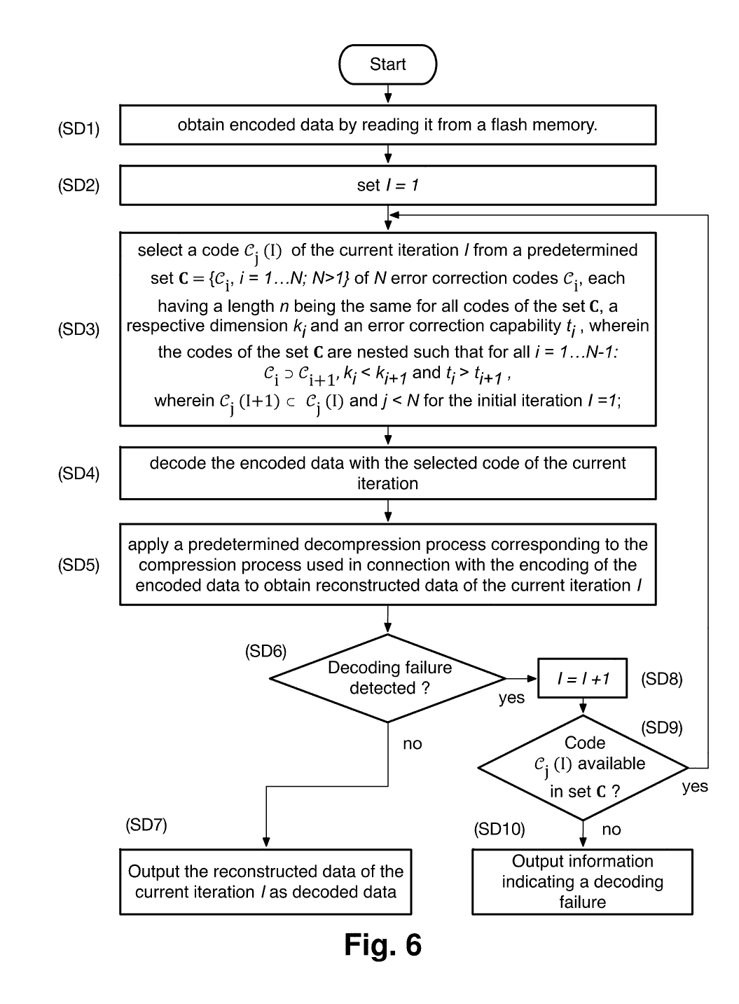

FIG. 6 is a flow chart illustrating an example embodiment of a corresponding decoding method according to the present invention. Again, for the purpose of illustration, this decoding method is exemplarily described in connection with a memory system 1, as illustrated in FIG. 1, the BAC of FIG. 3 and the coding schemes of FIG. 4. The method starts with a step SD1, wherein the memory controller 2, that serves as a coding device, now specifically as a decoding device (i.e. decoder), reads, i.e. retrieves, encoded data that was previously stored in the flash memory 3, e.g. by means of the encoding method of FIG. 5. As the method comprises an iteration process, in a further step SD2 an iteration index I is initialized as I=1.

Subsequent step SD3 comprises selecting a code [symbol] ⱼ(I) of the current iteration (i.e. I=1 for the initial iteration) from a predetermined set C={ [symbol] ᵢ, i=1 . . . N; N>1} of N error correction codes [symbol] ᵢ, each having a length n being the same for all codes of the set C, a respective dimension kᵢ and an error correction capability tᵢ. Therein, the codes of the set C are nested such that for all i=1 . . . N−1: [symbol] ᵢ⊃ [symbol] ᵢ₊₁, kᵢ>kᵢ+1 and tᵢ<tᵢ+1, wherein [symbol] ⱼ(I+1)⊂ [symbol] ⱼ(I). For I=1, i.e. the initial iteration: [symbol] ⱼ(I) is selected such that j<N. Then, in a further step SD4 the actual decoding of the retrieved encoded data is performed with the selected code of the current iteration, i.e. with [symbol] ⱼ(I) in case of the initial iteration. In a further step SD5, a decompression process corresponding to the compression process used for the encoding of the data is applied to the decoded data being output in step SD4, to obtain reconstructed data of the current iteration I.

A verification step SD6 follows, wherein a determination is made as to whether the decoding process of the current iteration I was successful. For example, this determination may be implemented in an equivalent way as a determination as to whether a coding failure occurred in the current iteration I. If the decoding of the current iteration I was successful, i.e. if no coding failure occurred (SD6—no), the reconstructed data of the current iteration I is output in a further step SD7 as a decoding result, i.e. as decoded data. Otherwise (SD6—yes), the iteration index I is incremented (I=I+1) in a step SD8 and a determination is made in a further step SD9, as to whether a code [symbol] ⱼ(I) for a next iteration is available in the set C. If this is the case (SD9—yes), the method branches back to step SD3 for the next iteration. Otherwise (SD9—no), i.e. when no further code is available for a next iteration, the overall decoding process fails and in step SD10 information indicating this coding failure is output, e.g. by sending a respective signal or message to host 4. Thus, the decoder running the method of FIG. 6, or more generally the decoding method of the present invention, can resolve which of the codes in the set C was actually used for the previous encoding of the data received from the channel, e.g. the flash memory 3.

For further illustration, the simplest case where N=2 is now considered. In this case, there are only two different codes [symbol] ₁ and [symbol] ₂ of length n and dimensions k₁and k₂ in the set C. The two codes are nested which means that [symbol] ₂is a subset of [symbol] ₁, i.e. [symbol] ₁⊃ [symbol] ₂. The code [symbol] ₂. has the smaller dimension k₂<k₁ and higher error correction capability t₂>t₁. If during the encoding process, e.g. with the method of FIG. 5, the data can be compressed such that the number of compressed bits is less or equal to k₂, the code [symbol] ₂ is used to encode the compressed data, otherwise the data is encoded using [symbol] ₁. Because [symbol] ₁⊃ [symbol] ₂, the decoder for [symbol] ₁ can also decode data encoded with [symbol] ₂ up to the error correction capability t₁. Thus, if the actual number of errors is less or equal to t₁ the decoding in the initial iteration based on [symbol] ₁ will be successful. If, however, the actual number of errors is greater than t₁, the decoder based on [symbol] ₁ fails. The failure can often be detected using algebraic decoding. Moreover, a failure can be detected based on error detection coding and based on the data compression scheme, because the number of data bits is known, the decoding fails if the number of reconstructed data bits is not consistent with the data block size. In cases where the decoding based on [symbol] ₁ fails, the decoder will continue the decoding using [symbol] ₂ which can correct up to t₂ errors. In summary, for sufficiently redundant data, the decoder can correct up to t₂ errors and will detect itself and use the correct code in which the data was previously encoded, for the decoding.

Reference is now made again to step SE4 of FIG. 5, which will now be discussed in more detail with reference to FIG. 7. The MTF algorithm transforms the probability distribution of the input symbols to a new output distribution. In the literature, there exist different proposals to estimate the probability distribution of the output of the MTF algorithm. For instance, in [32] the geometric distribution is proposed, whereas in [33] it is demonstrated that the indices are logarithmically distributed for ergodic sources, i.e., a codeword for the index i should be mapped to a codeword of length Lᵢ≈log₂(i). In [21], a discrete approximation of the log-normal distribution was proposed, i.e., the logarithm of the index is approximately normally distributed. However, these approaches consider only the MTF stage. In order to adapt the estimation of the output distribution to the two-stage processing of BTW and MTF, embodiments of the present inventions make use of a modification of the logarithmic distribution as proposed in [33]. The logarithmic distribution depends only on the number of symbols M. For any integer i [symbol] {1, . . . , M} the logarithmic probability distribution P(i) is defined as:

$$P ( i ) = \frac{1}{i {\sum }_{j = 1}^{M} \frac{1}{j}} . \qquad ( 1 )$$

Now consider the cascade of BWT and MTF. With the BWT, each symbol keeps its value but the order of symbols is changed. If the original string at the input of the BWT contains substrings that occurred often, then the transformed string will have several places where a single character is repeated multiple times in a row. For the MTF algorithm, these repeated occurrences result in sequences of output integers all equal to 1. Consequently, applying the BWT before the MTF algorithm changes the probability of rank 1. In order to take the BWT into account, embodiments of the present invention are based on a parametric logarithmic probability distribution

$$\begin{matrix}P ( 1 ) = {P}_{1} & \\ P ( i ) = \frac{1}{i ( {\sum }_{j = 2}^{M} \frac{1}{j} )} for i ∈ \{ 2 , . . . , M \} . & ( 2 )\end{matrix}$$

Note that with the ordinary logarithmic distribution P₁≈0.1633 for M=256. With the parametric logarithmic distribution, the parameter P₁ is the probability of rank 1 at the output of the cascade of BWT and MTF. P₁ may be estimated according to the relative frequencies at the output of the MTF for a real-world data model. In particular, in the following the Calgary and Canterbury corpora [34], [35] are considered. Both corpora include real-world test files in order to evaluate lossless compression methods. If the Canterbury corpus is used to determine the value of P₁, this results in P₁=0.4. Note that the Huffman code is not very sensitive to the actual value of P₁, i.e., for M=256 values in the range 0.37≤P₁≤0.5 result in the same code.

FIG. 7 depicts the different probability distributions as well as the actual relative frequencies for the Calgary corpus. Note that the compression gain is mainly determined by the probabilities of the low index values. As measure of the quality of the approximation of the output distribution, we use the Kullback-Leibler divergence, which is a non-symmetric measure of the difference between two probability distributions. Let Q(i) and P(i) be two probability distributions. The Kullback-Leibler divergence is defined as:

$$D ( Q ‖ P ) = {\sum }_{i} Q ( i ) {log}_{2} \frac{Q ( i )}{P ( i )} , \qquad ( 3 )$$

where a smaller value of the Kullback-Leibler divergence corresponds to a better approximation. Table I below presents values for the Kullback-Leibler divergence for the logarithmic distribution and the proposed parametric logarithmic distribution with P₁=0.4. Both distributions are compared to the actual output distribution of the BWT+MFT processing. All values where obtained for the Calgary corpus using data blocks of 1 kilobyte and M=256. Both transformations are initialized after each data block. Note that the proposed parametric distribution results in smaller values of the Kullback-Leibler divergence for all files in the corpus. These values can be interpreted as the expected extra number of bits per information byte that must be stored, if a Huffman code is used that is based on the estimated distribution P(i) instead of the true distribution Q(i). The Calgary corpus is also used to evaluate the compression gain.

TABLE I
KULLBACK-LEIBLER DIVERGENCE FOR THE ACTUAL OUTPUT
DISTRIBUTION OF THE BWT-MFT PROCESSING AND THE
APPROXIMATIONS FOR ALL FILES OF THE CALGARY CORPUS.

| file | log-dist. | parametric log. dist. |
|---|---|---|
| trans | 0.539 | 0.195 |
| progp | 0.700 | 0.276 |
| progl | 0.713 | 0.314 |
| progc | 0.486 | 0.207 |
| pic | 1.773 | 0.827 |
| paper6 | 0.455 | 0.264 |
| paper5 | 0.436 | 0.266 |
| paper4 | 0.467 | 0.346 |
| paper3 | 0.454 | 0.367 |
| paper2 | 0.477 | 0.363 |
| paper1 | 0.427 | 0.273 |
| obj2 | 0.559 | 0.125 |
| obj1 | 0.375 | 0.045 |
| news | 0.321 | 0.239 |
| geo | 0.160 | 0.046 |
| book2 | 0.456 | 0.320 |
| book1 | 0.454 | 0.447 |
| bib | 0.377 | 0.200 |

Table II below presents results for the average block length for different probability distributions and compression algorithms. All results present the average block length in bytes and were obtained by encoding data blocks of 1 kilobyte, where we used all files from the Calgary corpus. The results of the proposed algorithm are compared with the Lempel-Ziv-Welch (LZW) algorithm [24] and the algorithm presented in [21] which combines only MTF and Huffman coding. For the later algorithm, the Huffman coding is also based on an approximation of the output distribution of the MTF algorithm, where a discrete log-normal distribution is used. This distribution is characterized by two parameters, the mean value μ and the standard deviation σ. The probability density function for a log-normally distributed positive random variable x is:

$$p ( x ) = \frac{1}{\sqrt{2 π} σ x} exp ( - \frac{{( ln ( x ) - μ )}^{2}}{2 {σ}^{2}} ) . \qquad ( 4 )$$

For the integers i∈ {1, . . . , M} a discrete approximation of a log-normal distribution may be used, which results in the discrete probability distribution

$$P ( i ) = \frac{p ( α i )}{{\sum }_{j = 1}^{M} p ( α j )} , \qquad ( 5 )$$

Where α denotes a scaling factor. The mean value, the standard deviation, and the scaling factor α can be adjusted to approximate the actual probability distribution at the output of the MTF for a real-world data model. In Table II, the discrete log-normal distribution with mean value μ=3, standard deviation σ=3.7 and a scaling factor α=0.1 are used.

TABLE II
DETAILED RESULTS FOR THE CALGARY CORPUS FOR THE COMPRESSION
OF 1 KILOBYTE DATA BLOCKS. THE MEAN VALUES ARE THE AVERAGE
BLOCK LENGTH IN BYTES WHEREAS THE MAXIMUM VALUES ARE THE
WORST-CASE COMPRESSION RESULTS FOR EACH FILE.

| | BWT + MTF + Huffman | | MTF + Huffman | | | |
|---|---|---|---|---|---|---|
| | parametric log. dist. LCP = 16 | | μ = 3 & σ = 3.7 & α = 0.1 | | LZW | |
| file | mean | maximum | mean | maximum | mean | maximum |
| trans | 508.0 | 660.9 | 789.3 | 841.5 | 701.7 | 818.8 |
| progp | 442.3 | 607.5 | 763.5 | 804.5 | 634.2 | 755.0 |
| progl | 447.3 | 565.6 | 747 | 791.9 | 632.3 | 726.25 |
| progc | 530.9 | 624.6 | 791.3 | 836.8 | 714.0 | 800.0 |
| pic | 218.4 | 584.5 | 553.3 | 725.2 | 201.4 | 687.5 |
| paper6 | 557.3 | 623.0 | 770.1 | 811.7 | 719.4 | 790 |
| paper5 | 569.5 | 606.1 | 776.2 | 795.7 | 737.2 | 787.5 |
| paper4 | 580.4 | 644.1 | 771.7 | 823.8 | 726.0 | 775 |
| paper3 | 598.5 | 651.1 | 772.6 | 792.5 | 734.4 | 778.8 |
| paper2 | 583.1 | 652.3 | 772.8 | 803.4 | 720.6 | 792.5 |
| paper1 | 577.5 | 658.1 | 781.3 | 806.3 | 734.2 | 795 |
| obj2 | 495.3 | 908.3 | 842.6 | 925.8 | 684.7 | 1001.3 |
| obj1 | 580.7 | 930.5 | 804.2 | 939.5 | 716.4 | 1010.0 |
| news | 634.4 | 738.0 | 791.6 | 838.9 | 790.7 | 883.8 |
| geo | 747.6 | 799.3 | 851.1 | 883.6 | 856.3 | 907.5 |
| book2 | 575.9 | 656.0 | 771.4 | 828.8 | 725.7 | 795.0 |
| book1 | 626.6 | 677.1 | 769.3 | 787.3 | 739.0 | 788.8 |
| bib | 583.9 | 635.0 | 820.5 | 835.6 | 771.3 | 797.5 |

Table II presents the average block length in bytes for each file in the corpus. Moreover, the maximum values indicate the worst-case compression result for each file, i.e., these maximum values indicate how much redundancy can be added for error correction. Note that the proposed algorithm outperforms the LZW as well as the MTF-Huffman approach for almost all input files. Only for the image file named “pic”, the LZW algorithm achieves a better mean value.

Table III presents summarized results for the complete corpus, where the values are averaged over all files. The maximum values are also averaged over all files. These values can be considered as a measure of the worst-case compression. The results of the first two columns correspond to the proposed compression scheme using two different estimates for the probability distribution. The first column corresponds to the results with the proposed parametric distribution, where the parameter was obtained using data from the Canterbury corpus. The parametric distribution leads to a better mean value. The proposed data compression algorithm is compared to the LZW algorithm as well as to the parallel dictionary LZW (PDLZW) algorithm that is suitable for fast hardware implementations [25]. Note that the proposed data compression algorithm achieves significant gains compared with the other approaches.

TABLE III
RESULTS FOR THE AVERAGE BLOCK LENGTH IN BYTES PER 1 KILOBYTE BLOCK FOR
DIFFERENT PROBABILITY DISTRIBUTIONS AND COMPRESSION ALGORITHMS. MEAN AND
MAXIMUM VALUES ARE AVERAGED OVER ALL FILES IN THE CORPUS.

| | BWT + MTF + Huffman | BWT + MTF + Huffman | MTF + Huffman | | |
|---|---|---|---|---|---|
| | parametric log. dist. | log. dist. | μ = 3 & σ = 3.7 & σ = 0.1 | LWZ | PDLWZ |
| Calgary | | | | | |
| mean | 529.7 | 590.9 | 748.1 | 649.3 | 691.3 |
| maximum | 679 | 680.8 | 826.2 | 816 | 853.6 |
| Canterbury | | | | | |
| mean | 396.2 | 522.7 | 693.5 | 470.3 | 561.9 |
| maximum | 582.9 | 621.2 | 784.2 | 730.2 | 759.2 |

### Analysis of the Coding Scheme

In this section, an analysis of the error probability of the proposed coding scheme for the BAC is presented for the above-presented simple case where N=2 and thus there are only two

different codes [symbol] ₁ and [symbol] ₂ of length n and dimensions k₁ and k₂ in the set C. Based on these results, also some numerical results for an MLC flash will be presented.

For the binary asymmetric channel, the probability Pₑ of a decoding error depends on n₀ and n₁=n−n₀, i.e. the number of zeros and ones in a codeword. We denote probability of i errors in the positions with zeros by P₀(i). For the BAC, the number of errors for the transmitted zero bits follows a binomial distribution, i.e. the error pattern is a sequence of n₀ independent experiments, where an error occurs with probability p. We have

$${P}_{0} ( i ) = ( \begin{matrix}{n}_{0} \\ i\end{matrix} ) {{p}^{i} ( 1 - p )}^{{n}_{0} - i} . \qquad ( 6 )$$

Similarly, we obtain

$${P}_{1} ( j ) = ( \begin{matrix}{n}_{1} \\ j\end{matrix} ) {{q}^{j} ( 1 - q )}^{{n}_{1} - j} \qquad ( 7 )$$

for the probability of j errors in the positions with ones. Note that the number of errors in the positions with zeros and ones are independent. Thus, the probability to observe i errors in the positions with zeros and j errors in the positions with ones is P₀(i)P₁(j). We consider a code with error correction capability t. For such a code, we obtain the probability of correct decoding by

$${P}_{c} ( {n}_{0} , {n}_{1} , t ) = {\sum }_{i = 0}^{t} {\sum }_{j = 0}^{t - i} {P}_{0} ( i ) {P}_{1} ( j ) \qquad ( 8 )$$

and probability of a decoding error by

Pₑ(n₀, n₁, t)=1−P_{c}(n₀, n₁, t). (9)

The probability Pₑ(n₀, n₁) of a decoding error depends on n₀,n₁, and the error correction capability t [symbol] {t₁, t₂}. Moreover, these values depend on the data compression. If the data can be compressed such that the number of compressed bits is less or equal to k₂, [symbol] ₂is used with error correction capability t₂ to encode the compressed data. Otherwise the data is encoded using [symbol] ₁ with error correction capability t₁<t₂. Hence, the average error probability Pₑ may be defined as the expected value

Pₑ= [symbol] {Pₑ(n₀, n₁t)} (10)

where the average is taken over the ensemble of all possible data blocks.

In the following, results for example empirical data are presented. For the data model both the Calgary and the Canterbury corpus are used. The values of the error probabilities p and q are based on empirical data presented in [14]. Note that the error probability of a flash memory increases with the number of program/erase (P/E) cycles. The number of program/erase cycles determines the life time of a flash memory, i.e., the life time is the maximum number of program/erase cycles that can be executed while maintaining a sufficiently low error probability. Hence, the error probability for different numbers of program/erase cycles is now calculated.

The data is segmented into blocks of 1024 bytes, wherein each block is compressed and encoded independently from the other blocks. For ECC, a BCH code is considered which has an error correcting capability t₁=40, if uncompressed data is encoded. This code has the dimension k₁=8192 and a code length n=8752. For the compressed data, a compression gain of at least 93 bytes for each data block is achieved. Hence, one can double the correcting capability and use t₂=80 with k₂=7632(954 bytes) for compressed data. The remaining bits are filled with zero-padding as described above.

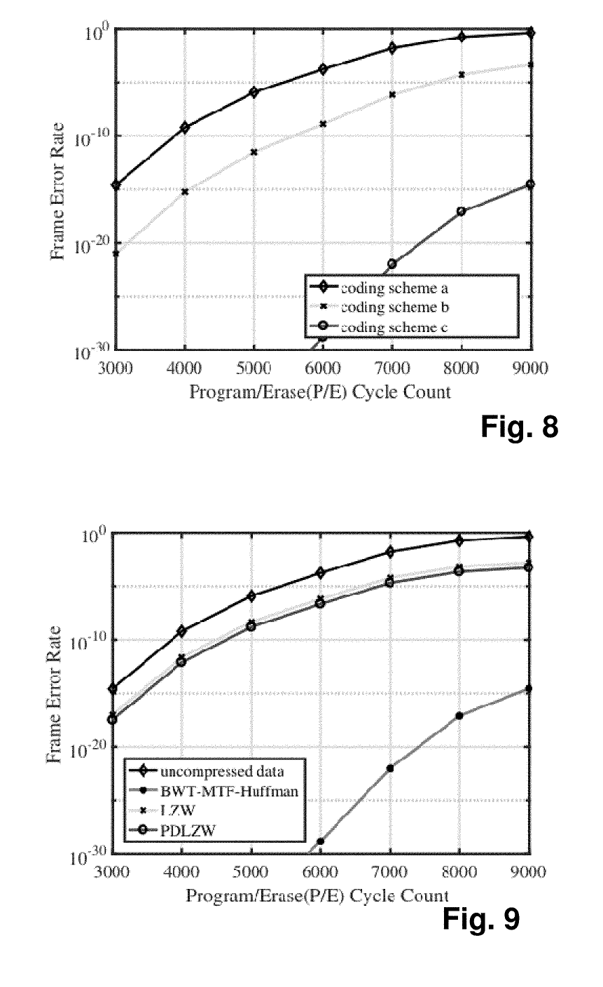

From this data processing, the actual numbers of zeros and ones for each data block are obtained. Finally, the error probability for each block is calculated according to Equation (10) and averaged over all data blocks. The numerical results are presented in FIG. 8, where a, b, and c denote the respective coding schemes according to FIG. 4. From these results, it can be observed that compression and zero-padding (curve b) improves the life time of the flash by more than 1000 program/erase cycles compared to ECC with uncompressed data (curve a). The higher error correcting capability (curve c) improves the life time by 4000 to 5000 program/erase cycles. For this analysis, a perfect error detection after decoding [symbol] ₁ is assumed. Hence, the frame error rates are too optimistic. The actual residual error rate depends on the error detection capability of the coding scheme. Nevertheless, the error detection capability should not affect the gain in terms of program/erase cycles.

FIG. 9 depicts results for different data compression algorithms for the Calgary corpus. All results with data compression are based on the coding scheme that uses additional redundancy for error correction (coding scheme c in FIG. 4). However, with the Calgary corpus there are blocks that might not be sufficiently redundant to add additional parity bits. This happens with the LZW and PDLZW algorithms. The LWZ algorithm results in 4 blocks and the PDLZW algorithm in 12 blocks of uncompressed blocks. These uncompressed blocks dominate the error probability.

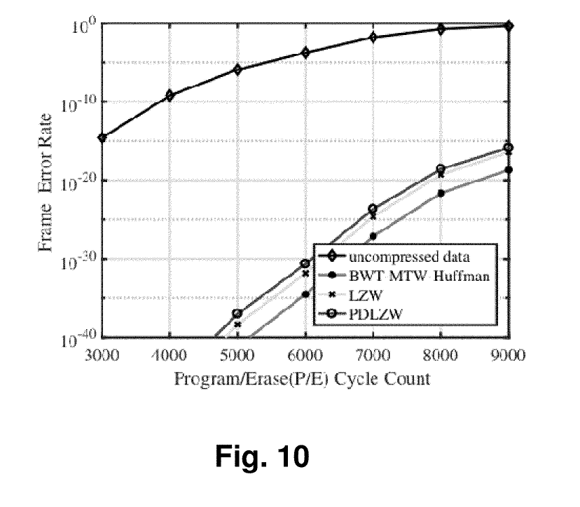

FIG. 10 shows a comparison of all schemes based on data from the Canterbury corpus. For this data model, all algorithms are able to compress all data blocks. However, the proposed algorithm improves the life time by 500 to 1000 cycles comparing with LZW and PDLZW schemes.

While above at least one example embodiment of the present invention has been described, it has to be noted that a great number of variations thereto exists. Furthermore, it is appreciated that the described exemplary embodiments only illustrate non-limiting examples of how the present invention can be implemented and that it is not intended to limit the scope, the application or the configuration of the herein-described apparatus' and methods. Rather, the preceding description will provide the person skilled in the art with constructions for implementing at least one exemplary embodiment of the invention, wherein it has to be understood that various changes of functionality and the arrangement of the elements of the exemplary embodiment can be made, without deviating from the subject-matter defined by the appended claims and their legal equivalents.

### LIST OF REFERENCE SIGNS

1 memory system
2 memory controller, including coding device
2a processing unit
2b embedded memory of memory controller
3 nonvolatile memory (NVM), particularly flash memory
4 host
A1 address line(s) to/from host
D1 data line(s) to/from host
C1 control line(s) to/from host
A2 address bus of NVM, e.g. flash memory
D2 data bus of NVM, e.g. flash memory
C2 control bus of NVM, e.g. flash memory

### REFERENCES

[1] R. Micheloni, A. Marelli, and R. Ravasio, Error Correction Codes for Non-Volatile Memories. Springer, 2008.
[2] A. Neubauer, J. Freudenberger, and V. Kuhn, “Coding Theory: Algorithms, Architectures and Applications. John Wiley & Sons, 2007.
[3] W. Liu, J. Rho, and W. Sung, “Low-power high-throughput BCH error correction VLSI design for multi-level cell NAND flash memories,” in IEEE Workshop on Signal Processing Systems Design and Implementation (SIPS), October 2006, pp. 303-308.
[4] J. Freudenberger and J. Spinner, “A configurable Bose-Chaudhuri-Hocquenghem codec architecture for flash controller applications,” Journal of Circuits, Systems, and Computers, vol. 23, no. 2, pp. 1-15, February 2014.
[5] C. Yang, Y. Emre, and C. Chakrabarti, “Product code schemes for error correction in MLC NAND flash memories,” IEEE Transactions on Very Large Scale Integration (VLSI) Systems, vol. 20, no. 12, pp. 2302-2314,December 2012.
[6] F. Sun, S. Devarajan, K. Rose, and T. Zhang, “Design of on-chip error correction systems for multilevel NOR and NAND flash memories,” IET Circuits, Devices Systems, vol. 1, no. 3, pp. 241-249, June 2007.
[7] S. Li and T. Zhang, “Improving multi-level NAND flash memory storage reliability using concatenated BCH-TCM coding,” IEEE Transactions on Very Large Scale Integration (VLSI) Systems, vol. 18, no. 10, pp.1412-1420, October 2010.
[8] J. Oh, J. Ha, J. Moon, and G. Ungerboeck, “RS-enhanced TCM for multilevel flash memories,” IEEE Transactions on Communications, vol. 61, no. 5, pp. 1674-1683, May 2013.
[9] J. Spinner, J. Freudenberger, and S. Shavgulidze, “A soft input decoding algorithm for generalized concatenated codes,” IEEE Transactions on Communications, vol. 64, no. 9, pp. 3585-3595, September 2016.
[10] J. Spinner, M. Rajab, and J. Freudenberger, “Construction of high-rate generalized concatenated codes for applications in non-volatile flash memories,” in 2016 IEEE 8th International Memory Workshop (IMW), May 2016, pp. 1-4.
[11] C. Gao, L. Shi, K. Wu, C. Xue, and E.-M. Sha, “Exploit asymmetric error rates of cell states to improve the performance of flash memory storage systems,” in Computer Design (ICCD), 2014 32nd IEEE International Conference on, October 2014, pp. 202-207.
[12] C. J. Wu, H. T. Lue, T. H. Hsu, C. C. Hsieh, W. C. Chen, P. Y.Du, C. J. Chiu, and C. Y. Lu, “Device characteristics of single-gate vertical channel (SGVC) 3D NAND flash architecture,” in IEEE 8th International Memory Workshop (IMW), May 2016, pp. 1-4.
[13] H. Li, “Modeling of threshold voltage distribution in NAND flash memory: A monte carlo method,” IEEE Transactions on Electron Devices, vol. 63, no. 9, pp. 3527-3532, September 2016.
[14] V. Taranalli, H. Uchikawa, and P. H. Siegel, “Channel models for multi-level cell flash memories based on empirical error analysis,” IEEE Transactions on Communications, vol. PP, no. 99, pp. 1-1, 2016.
[15] E. Yaakobi, J. Ma, L. Grupp, P. Siegel, S. Swanson, and J. Wolf, “Error characterization and coding schemes for flash memories, in “IEEEGLOBECOM Workshops, December 2010, pp. 1856-1860.
[16] E. Yaakobi, L. Grupp, P. Siegel, S. Swanson, and J. Wolf, “Characterization and error-correcting codes for TLC flash memories,” in International Conference on Computing, Networking and Communications (ICNC), January 2012, pp. 486-491.
[17] R. Gabrys, E. Yaakobi, and L. Dolecek, “Graded bit-error-correcting codes with applications to flash memory,” IEEE Transactions on Information Theory, vol. 59, no. 4, pp. 2315-2327, April 2013.
[18] R. Gabrys, F. Sala, and L. Dolecek, “Coding for unreliable flash memory cells,” IEEE Communications Letters, vol. 18, no. 9, pp. 1491-1494,September 2014.
[19] Y. Park and J.-S. Kim, “zFTL: power-efficient data compression support for NAND flash-based consumer electronics devices,” IEEE Transactions on Consumer Electronics, vol. 57, no. 3, pp. 1148-1156, August2011.
[20] N. Xie, G. Dong, and T. Zhang, “Using lossless data compression in data storage systems: Not for saving space,” IEEE Transactions on Computers, vol. 60, no. 3, pp. 335-345, March 2011.
[21] J. Freudenberger, A. Beck, and M. Rajab, “A data compression scheme for reliable data storage in non-volatile memories,” in IEEE 5th International Conference on Consumer Electronics (ICCE), September 2015, pp.139-142.
[22] T. Ahrens, M. Rajab, and J. Freudenberger, “Compression of short data blocks to improve the reliability of non-volatile flash memories”, in International Conference on Information and Digital Technologies (IDT), July 2016, pp. 1-4.
[23] P. M. Szecowka and T. Mandrysz, “Towards hardware implementation of bzip2 data compression algorithm,” in 16th International Conference Mixed Design of Integrated Circuits Systems (MIXDES), June 2009, pp.337-340.
[24] T. Welch, “A technique for high-performance data compression”, Computer, vol. 17, no. 6, pp. 8-19, June 1984.
[25] M.-B. Lin, J.-F. Lee, and G. E. Jan, “A lossless data compression and decompression algorithm and its hardware architecture,” IEEE Transactions on Very Large Scale Integration (VLSI) Systems, vol. 14,no. 9, pp. 925-936, September 2006.
[26] M. Grassl, P. W. Shor, G. Smith, J. Smolin, and B. Zeng, “New constructions of codes for asymmetric channels via concatenation,” IEEE Transactions on Information Theory, vol. 61, no. 4, pp. 1879-1886, April 2015.
[27] J. Freudenberger, M. Rajab, and S. Shavgulidze, “A channel and source coding approach for the binary asymmetric channel with applications to MLC flash memories,” in 11th International ITG Conference on Systems, Communications and Coding (SCC), Hamburg, February 2017, pp. 1-4.
[28] M. Burrows and D. Wheeler, A block-sorting lossless data compression algorithm. SRC Research Report 124, Digital Systems Research Center, Palo Alto, Calif., 1994.8
[29] P. Elias, “Interval and recency rank source coding: Twoon-line adaptive variable-length schemes,” IEEE Transactions on Information Theory, vol. 33, no. 1, pp. 3-10, January 1987.
[30] F. Willems, “Universal data compression and repetition times,” IEEE Transactions on Information Theory, vol. 35, no. 1, pp. 54-58, January 1989.
[31] D. A. Huffman, “A method for the construction of minimum-redundancy codes,” Proceedings of the IRE, vol. 40, no. 9, pp. 1098-1101, September 1952.
[32] J. Sayir, I. Spieler, and P. Portmann, “Conditional recency-ranking for source coding,” in Proc. IEEE Information Theory Workshop, June 1996,p. 61.
[33] M. Gutman, “Fixed-prefix encoding of the integers can be Huffman-optimal,” IEEE Transactions on Information Theory, vol. 36, no. 4, pp.936-938, July 1990.
[34] T. Bell, J. Cleary, and I. Witten, Text compression. Englewood Cliffs, N.J. Prentice Hall, 1990.
[35] M. Powell, “Evaluating lossless compression methods,” in New Zealand Computer Science Research Students' Conference, Canterbury, 2001, pp. 35-41.

What is claimed is:

1. A method of encoding data for transmission over a channel, the method being performed by a coding device and comprising:
obtaining input data to be encoded;
applying a predetermined data compression process to the input data to reduce redundancy, if any, to obtain compressed data;
selecting a code from a predetermined set C={ [symbol] ⱼ, i=1 . . . N; N>1) of N error correction codes [symbol] ᵢ, each having a length n being the same for all codes of the set C, a respective dimension kᵢ and error correction capability tᵢ, wherein the codes of the set C are nested such that for all i=1, . . . , N−1: [symbol] ᵢ⊃ [symbol] ᵢ₊₁, kᵢ>kᵢ₊₁ and tᵢ<tᵢ₊₁;
obtaining encoded data by encoding the compressed data with the selected code;
wherein selecting the code comprises determining a code [symbol] ⱼ with j [symbol] {1, . . . ,N} from the set C as the selected code, such that kⱼ≥m, wherein m is the number of symbols in the compressed data and m<n.

2. The method of claim 1, wherein determining the selected code comprises selecting that code from the set C as the selected code Cⱼ, which has the highest error correction capability tⱼ=max {tᵢ} among all codes in C for which kᵢ≥m.

3. The method of claim 1, wherein the channel is an asymmetric channel for which a first kind of data symbols exhibits a higher error probability than a second kind of data symbols, and obtaining encoded data comprises padding at least one symbol of a codeword of the encoded data, which symbol is not otherwise occupied by the applied code, by setting it to be a symbol of the second kind.

4. The method of claim 1, wherein applying the compression process comprises sequentially applying a Burrows-Wheeler-transform, BWT, a Move-to-front-coding, MTF, and a fixed Huffman encoding, FHE, to the input data to obtain the compressed data; and
wherein the fixed Huffman code to be applied in the FHE is derived from an estimate of the output distribution of the previous sequential application of both the BWT and the MTF to the input data.

5. The method of claim 4, wherein the estimate of the output distribution P(i) of the previous sequential application of the BWT and the MTF to the input data is determined as follows:
$$P ( 1 ) = {P}_{1} = const . \\ P ( i ) = \frac{1}{i ( {P}_{2} + {\sum }_{j = 2}^{M} \frac{1}{j} )} for i ∈ \{ 2 , . . . , M \}$$
wherein M is the number of symbols to be encoded by the FHE.

6. The method of claim 5, wherein M=256 and 0.37≤P₁≤0.5.

7. The method of claim 6, wherein M=256 and P₁=0.4.

8. The method of claim 1, wherein N=2.

9. A method of decoding data, the method being performed by a coding device and comprising:
obtaining encoded data, particularly data being encoded according to the method any one of the preceding claims;
iteratively:
performing a selection process comprising selecting a code [symbol] (I) of a current iteration I from a predetermined set C={ [symbol] ᵢ, i=1 . . . N; N>1} of N error correction codes [symbol] ᵢ, each having a length n being the same for all codes of the set C, a respective dimension kᵢ and an error correction capability tᵢ, wherein the codes of the set C are nested such that for all i=1 . . . N−1: [symbol] ᵢ⊃ [symbol] ᵢ₊₁, kᵢ>kᵢ₊₁ and tᵢ<tᵢ₊₁, wherein [symbol] (I)⊃ [symbol] (I+1) and [symbol] (1)⊃ [symbol] _{N} for an initial iteration I=1;
performing a decoding process comprising sequentially decoding the encoded data with the selected code of the current iteration I and applying a predetermined decompression process to obtain reconstructed data of the current iteration I;
performing a verification process comprising detecting whether the decoding process of the current iteration I resulted in a decoding failure; and
if in the verification process of the current iteration I a decoding failure was detected, proceeding with the next iteration I :=I+1; and
otherwise, outputting the reconstructed data of the current iteration I as decoded data.

10. The method of claim 9, wherein the verification process further comprises:
if for the current iteration I a decoding failure was detected, determining, before proceeding with the next iteration, whether another code [symbol] (I+1) with [symbol] (I+1)⊃ [symbol] (I) exists in the set C, and if not, terminating the iteration and outputting an indication of a decoding failure

11. The method of claim 9, wherein detecting whether the decoding process of the current iteration I resulted in a decoding failure comprises one or more of the following:
algebraic decoding; and
determining, whether the number of data symbols in the reconstructed data of the current iteration is inconsistent with a known corresponding number of data symbols in the original data to be reconstructed by the decoding.

12. The method of claim 9, wherein N=2.

13. A coding device, the coding device comprising:
a memory controller; and
wherein the coding device is configured to:
obtain input data to be encoded;
apply a predetermined data compression process to the input data to reduce redundancy, if any, to obtain compressed data;
select a code from a predetermined set C={ [symbol] ᵢ, i=1 . . . N; N>1} of N error correction codes [symbol] ᵢ, each having a length n being the same for all codes of the set C, a respective dimension kᵢ and error correction capability tᵢ, wherein the codes of the set C are nested such that for all i=1, . . . , N−1: [symbol] ᵢ⊃ [symbol] ᵢ₊₁, kᵢ>kᵢ₊₁ and tᵢ<tᵢ₊₁;
obtain encoded data by encoding the compressed data with the selected code; and
wherein selecting the code comprises determining a code [symbol] ⱼ with j ∈{1, . . . , N) from the set C as the selected code, such that kⱼ≥m, wherein m is the number of symbols in the compressed data and m<n.

14. The coding device of claim 13, wherein the coding device further comprises:
a storage medium and a processor, wherein the storage medium includes instructions executable by the processor to:
obtain the input data to be encoded;
apply the predetermined data compression process to the input data to reduce redundancy, if any, to obtain compressed data;
select the code from a predetermined set C={ [symbol] ᵢ, i=1 . . . N; N>1} of N error correction codes [symbol] ᵢ, each having a length n being the same for all codes of the set C, a respective dimension kᵢ and error correction capability tᵢ, wherein the codes of the set C are nested such that for all i=1, . . . , N−1: [symbol] ᵢ⊃ [symbol] ᵢ₊₁, kᵢ>kᵢ₊₁ and tᵢ<tᵢ₊₁;
obtain the encoded data by encoding the compressed data with the selected code.

15. The coding device of claim 13, wherein applying the compression process comprises sequentially applying a Burrows-Wheeler-transform, BWT, a Move-to-front-coding, MTF, and a fixed Huffman encoding, FHE, to the input data to obtain the compressed data; and
wherein the fixed Huffman code to be applied in the FHE is derived from an estimate of the output distribution of the previous sequential application of both the BWT and the MTF to the input data.

16. The coding device of claim 15, wherein the estimate of the output distribution P(i) of the previous sequential application of the BWT and the MTF to the input data is determined as follows:
$$P ( 1 ) = {P}_{1} = const . \\ P ( i ) = \frac{1}{i ( {P}_{2} + {\sum }_{j = 2}^{M} \frac{1}{j} )} for i ∈ \{ 2 , . . . , M \}$$
wherein M is the number of symbols to be encoded by the FHE.

17. The coding device of claim 16, wherein M=256 and 0.37≤P₁≤0.5.

18. The coding device of claim 17, wherein M=256 and P₁=0.4.

19. A coding device, the coding device comprising:
a memory controller; and
wherein the coding device is configured to:
obtain encoded data, particularly data being encoded according to the method any one of the preceding claims;
iteratively:
perform a selection process comprising selecting a code [symbol] (I) of a current iteration I from a predetermined set C={ [symbol] ᵢ, i=1 . . . N; N>1} of N error correction codes [symbol] ᵢ, each having a length n being the same for all codes of the set C, a respective dimension kᵢ and an error correction capability tᵢ, wherein the codes of the set C are nested such that for all i=1 . . . N−1: [symbol] ᵢ⊃ [symbol] ᵢ₊₁, kᵢ>kᵢ₊₁ and tᵢ<tᵢ₊₁, wherein [symbol] (I)⊃ [symbol] (I+1) and [symbol] (1)⊃ [symbol] _{N} for an initial iteration I=1;
perform a decoding process comprising sequentially decoding the encoded data with the selected code of the current iteration I and applying a predetermined decompression process to obtain reconstructed data of the current iteration I;
perform a verification process comprising detecting whether the decoding process of the current iteration I resulted in a decoding failure; and
if in the verification process of the current iteration I a decoding failure was detected, proceed with the next iteration I :=I+1; and
otherwise, output the reconstructed data of the current iteration I as decoded data.

20. The coding device of claim 19, wherein the coding device further comprises:
a storage medium and a processor, wherein the storage medium includes instructions executable by the processor to:
obtain the encoded data, particularly data being encoded according to the method any one of the preceding claims;
iteratively:
perform the selection process comprising selecting the code [symbol] (I) of a current iteration I from a predetermined set C={ [symbol] ᵢ, i=1 . . . N; N>1} of N error correction codes [symbol] ᵢ, each having a length n being the same for all codes of the set C, a respective dimension kᵢ and an error correction capability tᵢ, wherein the codes of the set C are nested such that for all i=1 . . . N−1: [symbol] ᵢ⊃ [symbol] ᵢ₊₁, kᵢ>kᵢ₊₁ and tᵢ<tᵢ₊₁, wherein [symbol] (I)⊃ [symbol] (I+1) and [symbol] (1) [symbol] _{N} for an initial iteration I=1;
perform the decoding process comprising sequentially decoding the encoded data with the selected code of the current iteration I and applying a predetermined decompression process to obtain reconstructed data of the current iteration I;
perform the verification process comprising detecting whether the decoding process of the current iteration I resulted in a decoding failure; and
if in the verification process of the current iteration I a decoding failure was detected, proceed with the next iteration I :=I+1; and
otherwise, output the reconstructed data of the current iteration I as decoded data
